(19) United States
(12) Patent Application Publication
(10) Pub. No.: US 2013/0279038 A1
(43) Pub. Date: Oct. 24, 2013

(54) COLOR FILTER AND MANUFACTURING METHOD THEREOF

(71) Applicant: Hsiao-hsien Chen, Shenzhen (CN)

(72) Inventor: Hsiao-hsien Chen, Shenzhen (CN)

(73) Assignee: SHENZHEN CHINA STAR OPTOELECTRONICS TECHNOLOGY CO., LTD., Shezhen, Guangdong (CN)

(21) Appl. No.: 13/695,284

(22) PCT Filed: Jul. 12, 2012
(86) PCT No.: PCT/CN2012/078546

§ 371 Date: Oct. 29, 2012

(30) Foreign Application Priority Data
Apr. 20, 2012 (CN) 201210118843.2

(51) Int. Cl. G03F 7/20; G02B 5/22

(52) U.S. Cl. CPC G03F 7/20; G02B 5/22
USPC 359/885; 430/7

(57) ABSTRACT

A manufacturing method of a color filter, includes: forming a black matrix on a substrate; adding photosensitive pigment material into the black matrix to form color resist units; exposing each color resist unit, in which different areas of each color resist unit are irradiated with light of different intensity; and developing each color resist unit to form a color resistance. Since the adjoining areas of each color resistance that adjoin the black matrix are flatter than the adjoining areas of each color resist unit that adjoin the black matrix, therefore, the surface of the transparent conductive layer covering the adjoining areas of each color resistance is also correspondingly flatter than before, which allows the liquid crystal molecules in the transparent conductive layer to be regularly arranged to improve the contrast of the color filter layer.

### BACKGROUND

1. Technical Field

The present disclosure relates to liquid crystal displaying technologies and, particularly, to a color filter and a manufacturing method thereof.

2. Description of Related Art

Liquid crystal displays (LCDs) are capable of displaying colored images via color filters. When a backlight source radiates light, the light transmits through the red, green, and blue primary color filter layers of the color filter to form the three primary colors including red, green, and blue, which are further mixed to form the colored images. Therefore, the color filter is an important component of the LCD.

Referring to FIG. 1, in the manufacturing process of a present liquid crystal panel, the color filter is manufactured according to the following method: forming a black matrix 50 on a transparent substrate 10; after the black matrix 50 is formed, injecting three kinds of pigment material including red ink, green ink, and blue ink into the spaces in the black matrix 50; baking the pigment material and then cooling it to form a red color resist 20, a green color resist 30, and a blue color resist 40. Since the material of the black matrix 50 is repulsive in relative with the pigment material, that is, the pigment material is repelled from the black matrix 50, which causes the adjoining areas of the red color resist 20, the green color resist 30, and the blue color resist 40 adjoining the black matrix 50 to be rough. This may result in the undesirable alignment of the liquid crystal molecules and increase the brightness of the dark state, and further results in the abnormality of the contrast between the bright images and the dark images of the liquid crystal panel.

### SUMMARY

The present disclosure provides a manufacturing method of a color filter, includes: forming a black matrix on a substrate; adding photosensitive pigment material into the black matrix to form color resist units each which includes adjoining areas adjoining the black matrix and has a thickness being the same as that the black matrix except the adjoining areas; exposing each color resist unit, in which thicknesses of different areas of each color resist unit are inversely proportional to intensity of light being radiated thereto; and developing each color resist unit to form a color resistance.

Preferably, the step of developing each color resist unit to form a color resistance includes:

exposing each color resist unit using a photomask having light-blocking areas, semi-transparent areas, and transparent areas, and the intensity of the light transmitting through the photomask is inversely proportional to the thickness of the corresponding color resist unit.

Preferably, each transparent area of the photomask corresponds to an area of each color resist unit having the minimum thickness, and ultraviolet light is capable of transmitting through the photomask completely to irradiate the corresponding area of the color resist unit after transmitting through the photomask; and each semi-transparent area corresponds to the other areas of each color resist unit, and the ultraviolet light is capable of partly transmitting through the photomask to irradiate the corresponding areas.

Preferably, the step of developing each color resist unit to form a color resistance includes:

developing each color resist unit by using developer solution, in which a layer of each color resist unit having a thickness reversely proportional to the intensity of the ultraviolet light being radiated thereto is removed from each color resist layer.

Preferably, the thickness of the area of the color resist unit which has the minimum thickness remains unchanged after the color resist unit is developed.

Preferably, the pigment material includes photo initiator therein.

Preferably, the pigment material includes red pigment material, green pigment material, and blue pigment material; the red pigment material, green pigment material, and the blue pigment material are dropped into the corresponding spaces defined in the black matrix to respectively form red color resist units, green color resist units, and blue color resist units, and the respective red color resist unit, respective green color resist unit, and respective blue color resist unit are spacedly disposed in this order.

Preferably, the manufacturing method further includes the following step after the step of developing each color resist unit to form a color resistance:

forming a transparent conductive layer on a surface of the black matrix and each color resistance.

The present disclosure further provides another manufacturing method of a color filter, includes: forming a black matrix on a substrate; filling the black matrix with photosensitive pigment material to form color resist units; exposing each color resist unit, in which thicknesses of different areas of each color resist unit are inversely proportional to intensity of light being radiated thereto; and developing the color resist units to form color resistances.

Preferably, the step of developing the color resist units to form color resistances includes:

developing the color resist units via a photomask having light-blocking areas, semi-transparent areas, and transparent areas; and the intensity of the ultraviolet light transmitting through the photomask is inversely proportional to a thickness of the corresponding color resist unit.

Preferably, each transparent area corresponds to an area of each color resist unit having the minimum thickness, and ultraviolet light is capable of transmitting through the photomask to irradiate the corresponding part of each color resist unit; each semi-transparent area corresponds to the other areas of each color resist unit, and the ultraviolet light is capable of partly transmitting through the photomask to irradiate the other area of each color resist unit.

Preferably, the step of developing the color resist units to form color resistances includes:

developing the color resist units by using developer solution, in which a layer of each color resist unit having a thickness reversely proportional to the intensity of the ultraviolet light being radiated thereto is removed from each color resist layer.

Preferably, the thickness of the area of the color resist unit having the minimum thickness remains unchanged after the color resist unit is developed.

Preferably, the pigment material includes photo initiator therein.

Preferably, the pigment material includes red pigment material, green pigment material, and blue pigment material; the red pigment material, green pigment material, and the blue pigment material are dropped into the corresponding spaces defined in the black matrix to respectively form red color resist units, green color resist units, and blue color resist units, and the respective red color resist unit, respective green color resist unit, and respective blue color resist unit are spacedly disposed in this order.

Preferably, the manufacturing method further includes the following step after the step of developing the color resist units to form color resistances:

forming a transparent conductive layer on a surface of the black matrix and each color resistance.

The present disclosure further provides a color filter. The color filter includes a substrate; a black matrix disposed on the substrate; and color resistances, disposed on the substrate and formed in the black matrix; the color resistances are made of photosensitive material and include adjoining areas adjoining the black matrix, and thicknesses of areas of each color resistance except the adjoining areas are the same as that of the black material.

Preferably, the photosensitive material includes photo initiator therein.

Preferably, a transparent conductive layer is formed on the black matrix and the color resistance.

In the present disclosure, each color resist unit is irradiated with light of intensity inversely proportional to the thickness thereof, therefore, after being developed, the adjoining areas of each color resist unit that adjoin the black matrix are flatter than before, which improves the contrast of the color filter.

### DESCRIPTION OF THE DRAWINGS

Many aspects of the embodiments can be better understood with reference to the following drawings. The components in the drawings are not necessarily dawns to scale, the emphasis instead being placed upon clearly illustrating the principles of the embodiments. Moreover, in the drawings, like reference numerals designate corresponding parts throughout the several views.

FIG. 1 is a schematic view of a color filter in the prior art;

FIG. 2 is a flow chart of a manufacturing method of a color filter in accordance with one embodiment of the present disclosure;

FIG. 3 is a schematic view illustrating the process of forming a black matrix according to the manufacturing method of FIG. 2;

FIG. 4 is a schematic view illustrating the process of forming color resist units according to the manufacturing method of FIG. 2;

FIG. 5 is an enlarged view of the portion A shown in FIG. 4;

FIG. 6 is a schematic view illustrating the process of exposing the color resist units according to the manufacturing method of FIG. 2;

FIG. 7 is a schematic view showing intensity of light transmitting through a photomask corresponding to thickness of each color resist unit;

FIG. 8 is a schematic view of the developed color resist and black matrix;

FIG. 9 is a an enlarged view of the portion B shown in FIG. 8;

FIG. 10 is a schematic view of a color filter in accordance with one embodiment of the present disclosure.

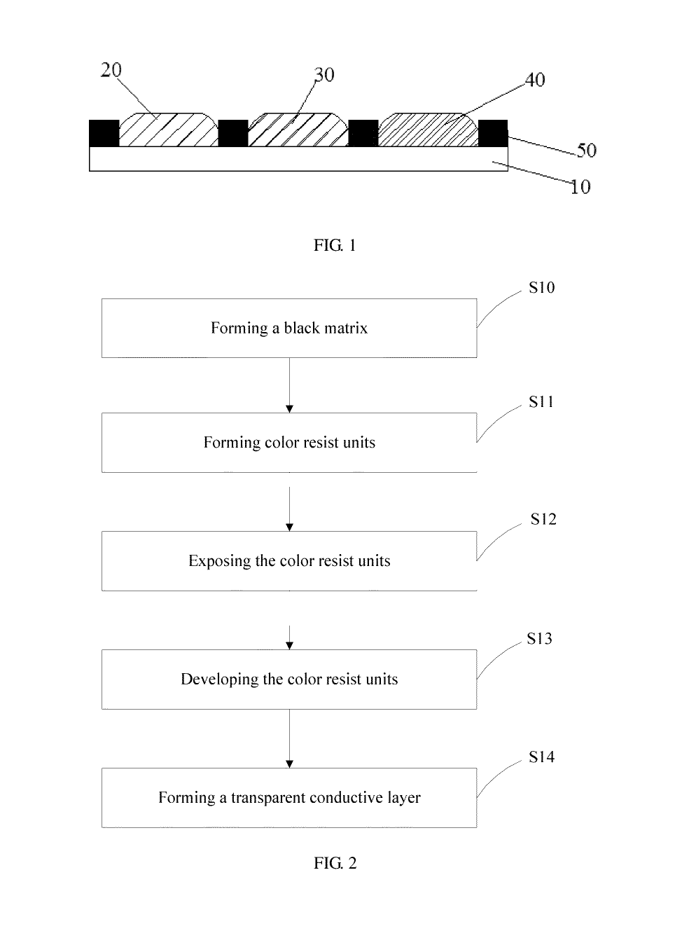

### DETAILED DESCRIPTION

The disclosure is illustrated by way of example and not by way of limitation in the figures of the accompanying drawings in which like references indicate similar elements. It should be noted that references to “an” or “one” embodiment is this disclosure are not necessarily to the same embodiment, and such references mean at least one.

Referring to FIG. 2, the present disclosure provides a manufacturing method of a color filter, which includes the following steps:

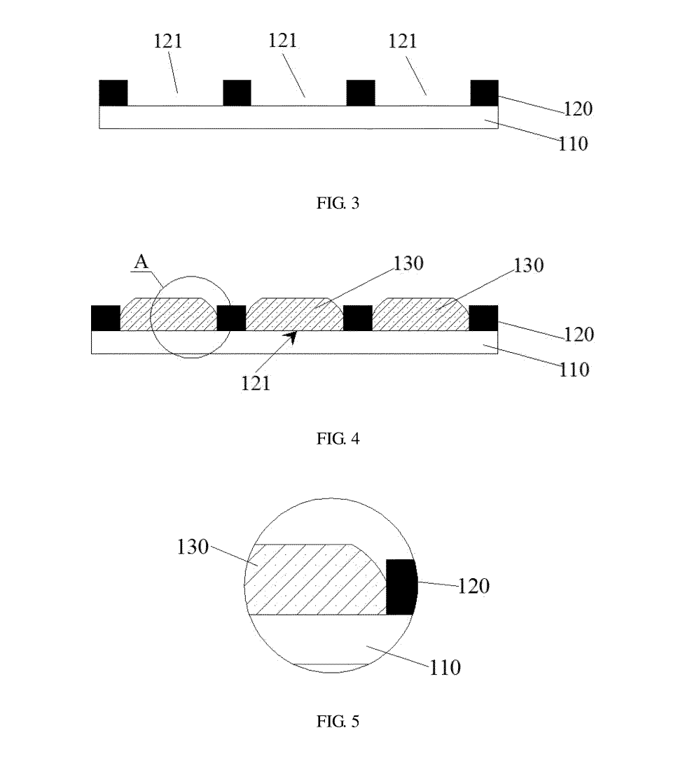

Step S10, forming a black matrix. Specifically, at first, providing a substrate 110 made of glass or plastic material such as polymethylmethacrylate or polycarbonate; secondly, cleaning the substrate 110 to remove impurities on a surface of the substrate 110, forming a photoresist layer on the substrate 110, irradiating the photoresist layer with ultraviolet light transmitting through a photomask, and developing the photoresist layer by using developer solution to form a black matrix 120 in the photoresist layer. As shown in FIG. 3, a number of spaces 121 are defined in the black matrix 120. In practical situation, the manufacturing method is not limited to the embodiment. Various changes and modifications will become apparent to those skilled in the art.

Step S11, forming color resist units.

The color resist units are made of photosensitive pigment material, which includes photo initiator therein. The photo initiator may be 2,2′-bis(o-methyl phenyl)-4,4′,5,5′-four phenyl two imidazole or 2,2′-bis(o ethyl phenyl)-4,4′,5,5′-four phenyl two imidazole, or the combination thereof.

The pigment material is dropped into the spaces 121 of the black matrix 120 via a multi-head ink-jet array to form color resist units 130, as shown in FIGS. 3 and 4. Since the pigment material is repelled from the black matrix 120, adjoining areas of each color resist unit 130 adjoining the black matrix 120 have thicknesses less than thicknesses of the other areas of the corresponding color resist unit 130, as shown in FIG. 5, which is an enlarged view of the adjoining areas of each color resist unit 130 adjoining the black matrix 120.

The pigment material includes red pigment material, green pigment material, and blue pigment material. The red pigment material, green pigment material, and blue pigment material are correspondingly dropped into the spaces 121 to form red color resist units, green color resist units, and blue color resist units. The respective red color resist unit, respective green color resist units, and respective blue color resist units are spacedly disposed in this order.

Step S12, exposing the color resist units.

The color resist units are pre-baked to be dry and then are exposed via a photomask.

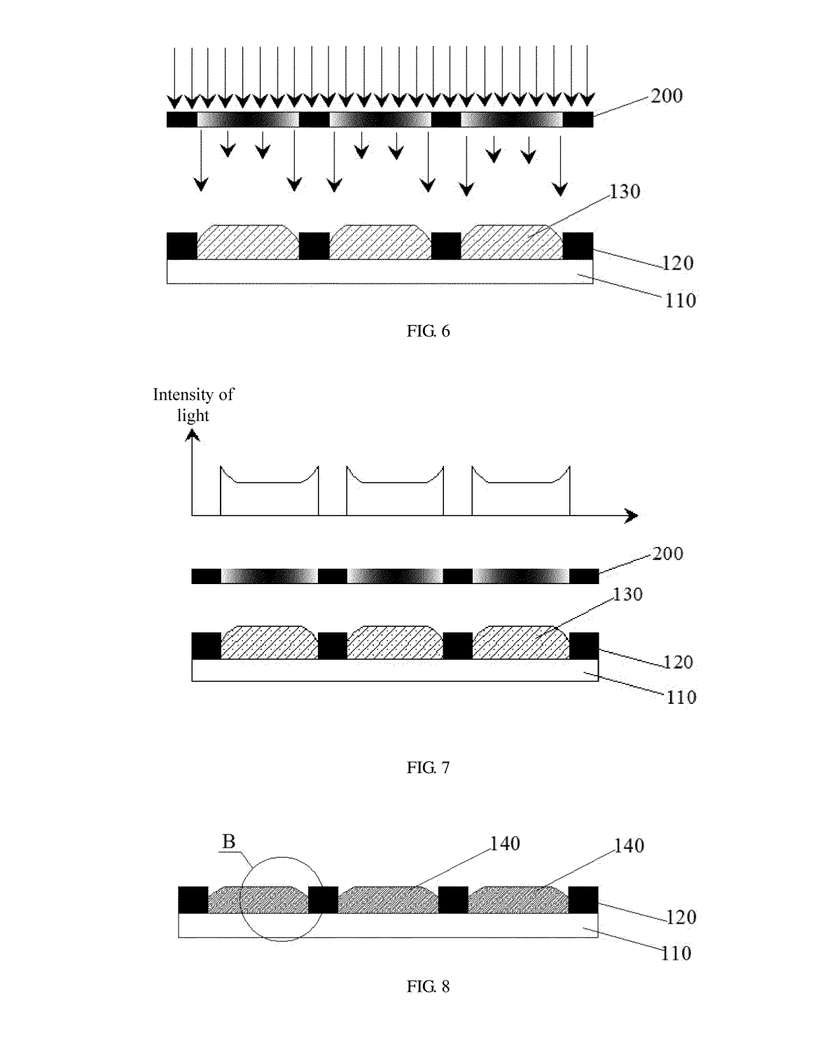

Referring to FIGS. 6 and 7, in which FIG. 6 is a schematic view illustrating the process of exposing the color resist units and FIG. 7 is a schematic view showing the intensity of the light transmitting through the photomask corresponding to the thickness of each color resist unit. The photomask 200 includes light-blocking areas, semi-transparent areas, and transparent areas. The intensity of the ultraviolet light (shown as the arrow in FIG. 6) transmitting through the photomask 200 is inversely proportional to the thickness of each color resist unit being irradiated with the ultraviolet light. That is, the intensity of the ultraviolet light, which irradiates an area of each color resist unit 130 having a greater thickness, is relatively lower; and the intensity of the ultraviolet light, which irradiates the other areas of each color resist unit 130 having a less thicknesses, is relatively higher. In this way, the intensity of the ultraviolet light irradiating the adjoining areas of each color resist unit 130 adjoining the black matrix 120 is higher than that of the ultraviolet light irradiating the other areas of the corresponding color resist unit 130. Preferably, each transparent area of the photomask corresponds to the area of each color resist unit 130 having the minimum thickness, thus, the ultraviolet light is capable of transmitting through the photomask 200 completely to irradiate the corresponding area of the color resist units 130; each semi-transparent area of the photomask corresponds to the other areas of each color resist unit 130, thus, the ultraviolet light is capable of partly transmitting through the photomask 200 partially to irradiate the corresponding areas of the corresponding color resist unit 130. As the thickness of each color resist unit 130 increases, the intensity of the light being radiated thereto after transmitting through the photomask 200 gradually reduces. In the embodiment, since there is no need to expose the black matrix 120, the photomask is disposed in a way allowing the light-blocking areas to correspond to the black matrix 120 to block the ultraviolet light from being radiated to the black matrix 120.

Step S13, developing the color resist units 130.

After the color resist units 130 are exposed, the color resist units 130 are further developed by using developer solution. In the developing process, the developer solution removes a layer from each color resist unit 130. Since different areas of each color resist unit 130 are irradiated with ultraviolet light of different intensity, the thickness of the layer is varied from area to area of each color resist unit 130. Additionally, the thickness of the removed layer of each color resist unit 130 by the developer solution is inversely proportional to the intensity of the light irradiating thereon, that is, to the area of each color resist 130 being irradiated with ultraviolet light of higher intensity, the part of the removed layer corresponding thereto has a less thickness; and to the area of each color resist 130 being irradiated with ultraviolet light of lower intensity, the part of the removed layer corresponding thereto has a greater thickness.

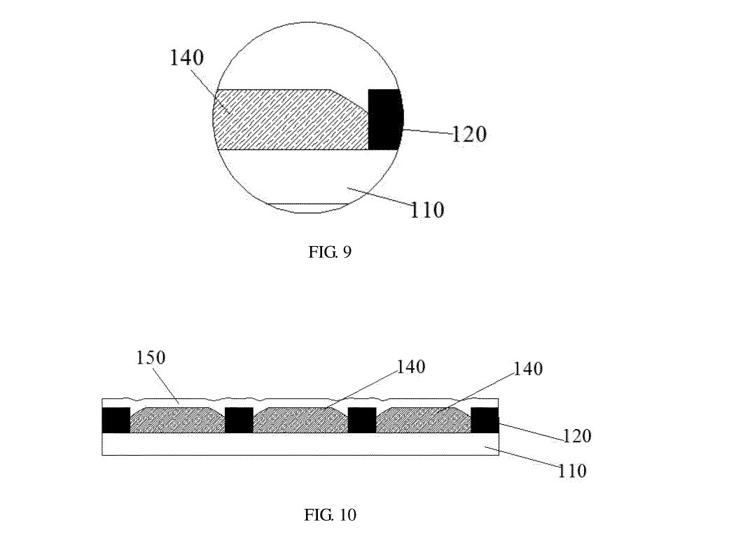

Since the adjoining areas of each color resist unit 130 that adjoin the black matrix 120 are irradiated with ultraviolet light of relatively higher intensity, and the other areas of the color resist unit 130 are irradiated with ultraviolet light of relatively lower intensity, and the area of the color resist unit 130 having the minimum thickness is irradiated with ultraviolet light of the highest intensity, therefore, the part of the removed layer corresponding to the thinnest area of the color resist unit 130 has the minimum thickness. Preferably, after the color filter is developed, the thickness of the area of the color resist units 130 which has the minimum thickness, substantially remains unchanged, while the thicknesses of the other areas thereof are reduced. After being developed, the color resist units 130 form the color resistances 140 as shown in FIG. 8. The thickness of each color resistance 140, except the adjoining areas thereof, is the same as the thickness of the black matrix 120. As shown in FIG. 9, which is an enlarged view of the adjoining areas of the color resistance 140 adjoining the black matrix 120, the surfaces of the adjoining areas of the color resistance 140 adjoining the black matrix 120 are relatively flatter after being developed, as shown in FIG. 5.

The color resistances 140 includes red color resistances, green color resistances, and blue color resistances respectively formed by developing the red color resist units, the green color resist units, and the blue color resist units.

Step S14, forming a transparent conductive layer 150.

Baking the color resistances 140, and forming the transparent conductive layer on the surface of the black matrix 120 and the color resistances 140, as shown in FIG. 10. The transparent conductive layer 150 may be a film made of indium tin oxide.

Since the adjoining areas of each color resistance 140 adjoining the black matrix 120 are flatter than before after the color resist units 130 are developed, the surface of the transparent conductive layer covering the adjoining areas is also correspondingly flatter than before, which allows the liquid crystal molecules in the transparent conductive layer to be regularly arranged to improve the contrast of the color filter layer.

The present disclosure further provides a color filter manufactured by the above manufacturing method. As shown in FIG. 10, the color filter includes a substrate 110, a black matrix 120 formed on the substrate 110, color resistances 140 formed in the black matrix 120, and a transparent conductive layer 150 covering the color resistances 140 and the black matrix 120. The color resistances 140 include red color resistances, green color resistances, and blue color resistances disposed in this order.

The color resistances 140 are made of pigment material including red pigment material, green pigment material, and blue pigment material. The pigment material is photosensitive material and includes photo initiator therein. The photo initiator may be 2,2′-bis(o-methyl phenyl)-4,4′,5,5′-four phenyl two imidazole or 2,2′-bis(o ethyl phenyl)-4,4′,5,5′-four phenyl two imidazole, or the combination thereof.

The pigment material is dropped into the black matrix 120 via a multi-head ink-jet array to form color resist units 130, as shown in FIGS. 3 and 4. Since the pigment material is repelled from the black matrix 120, thicknesses of adjoining areas of each color resist unit 130 adjoining the black matrix 120 are less than the thicknesses of the other areas thereof.

After being dried, the color resist units 130 are exposed via the photomask 200. As mentioned above, the photomask 200 is capable of providing continuously changing energy and the intensity of the ultraviolet light transmitting through the photomask is inversely proportional to the thickness of each color resist unit being irradiated. That is, the intensity of the ultraviolet light irradiating the area of each color resist unit having a less thickness is relatively higher, and the intensity of the ultraviolet light irradiating the other areas of each color resist unit having greater thicknesses is relatively lower.

After being developed, the color resist units 130 are developed by using the developer solution to form the color resistance 140. As mentioned above, the developer solution removes a layer which has a thickness varies from area to area from each color resist unit 130. To the area of each color resist 130 being irradiated with ultraviolet light of higher intensity, the part of the removed layer corresponding thereto has a less thickness; and to the area of each color resist 130 being irradiated with ultraviolet light of lower intensity, the part of the removed layer corresponding thereto has a greater thickness, which allows the adjoining area of the color resistance 140 adjoining the black matrix 120 to be flatter than before after being developed.

Since the adjoining areas of each color resistance 140 adjoining the black matrix 120 are flatter than before after the color resist units 130 are developed, the surface of the transparent conductive layer covering the adjoining area is also correspondingly flatter than before, which allows the liquid crystal molecules in the transparent conductive layer to be regularly arranged to improve the contrast of the color filter layer.

Even though information and the advantages of the present embodiments have been set forth in the foregoing description, together with details of the mechanisms and functions of the present embodiments, the disclosure is illustrative only; and that changes may be made in detail, especially in matters of shape, size, and arrangement of parts within the principles of the present embodiments to the full extend indicated by the broad general meaning of the terms in which the appended claims are expressed.

What is claimed is:

1. A manufacturing method of a color filter, comprising:
forming a black matrix on a substrate;
adding photosensitive pigment material into the black matrix to form color resist units each which comprises adjoining areas adjoining the black matrix and has a thickness being the same as that the black matrix except the adjoining areas;
exposing each color resist unit, in which thicknesses of different areas of each color resist unit are inversely proportional to intensity of light being radiated thereto; and
developing each color resist unit to form a color resistance.

2. The manufacturing method as claimed in claim 1, wherein the step of developing each color resist unit to form a color resistance comprises:
exposing each color resist unit using a photomask having light-blocking areas, semi-transparent areas, and transparent areas, and the intensity of the light transmitting through the photomask is inversely proportional to the thickness of the corresponding color resist unit.

3. The manufacturing method as claimed in claim 2, wherein each transparent area of the photomask corresponds to an area of each color resist unit having the minimum thickness, and ultraviolet light is capable of transmitting through the photomask completely to irradiate the corresponding area of the color resist unit; and each semi-transparent area corresponds to the other areas of each color resist unit, and the ultraviolet light is capable of partly transmitting through the photomask to irradiate the corresponding areas.

4. The manufacturing method as claimed in claim 1, wherein the step of developing each color resist unit to form a color resistance comprises:
developing each color resist unit by using developer solution, in which a layer of each color resist unit having a thickness reversely proportional to the intensity of the ultraviolet light being radiated thereto is removed from each color resist layer.

5. The manufacturing method as claimed in claim 4, wherein the thickness of the area of the color resist unit which has the minimum thickness remains unchanged after the color resist unit is developed.

6. The manufacturing method as claimed in claim 1, wherein the pigment material comprises photo initiator therein.

7. The manufacturing method as claimed in claim 6, wherein the pigment material comprises red pigment material, green pigment material, and blue pigment material; the red pigment material, green pigment material, and the blue pigment material are dropped into the corresponding spaces defined in the black matrix to respectively form red color resist units, green color resist units, and blue color resist units, and the respective red color resist unit, respective green color resist unit, and respective blue color resist unit are spacedly disposed in this order.

8. The manufacturing method as claimed in claim 1 further comprising the following step after the step of developing each color resist unit to form a color resistance comprises:
forming a transparent conductive layer on a surface of the black matrix and each color resistance.

9. A manufacturing method of a color filter, comprises:
forming a black matrix on a substrate;
filling the black matrix with photosensitive pigment material to form color resist units;
exposing each color resist unit, in which thicknesses of different areas of each color resist unit are inversely proportional to intensity of light being radiated thereto; and
developing the color resist units to form color resistances.

10. The manufacturing method as claimed in claim 9, wherein the step of developing the color resist units to form color resistances comprises:
developing the color resist units via a photomask having light-blocking areas, semi-transparent areas, and transparent areas; and the intensity of the ultraviolet light transmitting through the photomask is inversely proportional to a thickness of the corresponding color resist unit.

11. The manufacturing method as claimed in claim 10, wherein each transparent area corresponds to an area of each color resist unit having the minimum thickness, and ultraviolet light is capable of transmitting through the photomask completely to irradiate the corresponding part of each color resist unit; each semi-transparent area corresponds to the other areas of each color resist unit, and the ultraviolet light is capable of partly transmitting through the photomask to irradiate the other areas of each color resist unit.

12. The manufacturing method as claimed in claim 9, wherein the step of developing the color resist units to form color resistances comprises:
developing the color resist units by using developer solution, in which a layer of each color resist unit having a thickness reversely proportional to the intensity of the ultraviolet light being radiated thereto is removed from each color resist layer.

13. The manufacturing method as claimed in claim 12, wherein the thickness of the area of the color resist unit having the minimum thickness remains unchanged after the color resist unit is developed.

14. The manufacturing method as claimed in claim 9, wherein the pigment material comprises photo initiator therein.

15. The manufacturing method as claimed in claim 14, wherein the pigment material comprises red pigment material, green pigment material, and blue pigment material; the red pigment material, green pigment material, and the blue pigment material are dropped into the corresponding spaces defined in the black matrix to respectively form red color resist units, green color resist units, and blue color resist units, and the respective red color resist unit, respective green color resist unit, and respective blue color resist unit are spacedly disposed in this order.

16. The manufacturing method as claimed in claim 9 further comprising the following step after the step of developing the color resist units to form color resistances comprises:
forming a transparent conductive layer on a surface of the black matrix and each color resistance.

17. A color filter, comprising:
a substrate;
a black matrix disposed on the substrate; and
color resistances, disposed on the substrate and formed in the black matrix; the color resistances being made of photosensitive material and comprising adjoining areas adjoining the black matrix, and thicknesses of areas of each color resistance except the adjoining areas being the same as that of the black material.

18. The color filter as claimed in claim 17, wherein the photosensitive material comprises photo initiator therein.

19. The color filter as claimed in claim 18, wherein a transparent conductive layer is formed on the black matrix and the color resistance.
